(19) United States
(12) Patent Application Publication
(10) Pub. No.: US 2008/0288852 A1
(43) Pub. Date: Nov. 20, 2008

(54) MULTICARRIER COMMUNICATION SYSTEM CAPABLE OF SWITCHING MODULATION SCHEMES DURING COMMUNICATION

(75) Inventors: Teruaki Uehara, Sagamihara (JP); Masato Yamazaki, Tokyo (JP); Hiroyuki Akiyama, Chibasi (JP)

Correspondence Address: Studebaker & Brackett PC, 1890 Preston White Drive, Suite 105, Reston, VA, 20191, US

(73) Assignee: OKI ELECTRIC INDUSTRY CO., LTD., Tokyo (JP)

(21) Appl. No.: 11/945,602

(22) Filed: Nov. 27, 2007

(30) Foreign Application Priority Data
Nov. 27, 2006 (JP) 2006-319202

(51) Int. Cl. H03M 13/03; G06F 11/10

(52) U.S. Cl. 714/786; 714/746; 714/E11.032

(57) ABSTRACT

A multicarrier wireless communication system is capable of switching the modulation scheme used by each carrier during communication. This communication system includes error detectors for detecting error bits separately for respective carriers by comparing the data block of each carrier before and after correction. The modulation scheme used by a particular carrier is switched to an appropriate modulation scheme, when the S/N ratio of the particular carrier is deteriorated or improved, on the basis of the information about the corrected error bits.

### BACKGROUND OF THE INVENTION

1. Field of the Invention

The present invention relates to a communication system based on a multiple carrier transmission scheme, and, more specifically, to a wireless multiple carrier communication system.

2. Description of the Background Art

Recent telecommunications systems are often based on multiple carrier, or multicarrier, transmission schemes such as OFDM (Orthogonal Frequency Division Multiplexing) and DMT (Discrete Multi-Tone). In the case of communication system based on such a multicarrier transmission scheme, it is necessary to determine a modulation scheme optimal for a specific carrier for the purpose of accomplishing effective transmission.

Because of this, conventionally, signal-to-noise (S/N) ratios are measured by use of training signals in advance of starting communication to designate, on the basis of the result of the measurement, an optimal modulation scheme for each carrier such as to transmit a largest amount of data (for example, refer to Japanese patent laid-open publication No. 163823/1999). In this type of communication system, the S/N ratios for the respective carriers are measured only just when starting the communication, and it is thus impossible to adaptively designate an optimal modulation scheme currently appropriate for the time-varying S/N ratio of each carrier. Therefore, when the characteristic of the carrier changes so that the transmission can no longer be continued, the training signals are transmitted again to reassign such a modulation scheme for the changed carrier that the largest amount of data can be transmitted.

For example, with reference to FIG. 12, it is considered that carriers 1, 2, 3 and 4 are used to perform communication of 4 bit/carrier in which up to 4 bits of 16-bit data can be corrected by error correction. In such a case, when error occurs in the carrier 1 from time T1 to time T2 and in the carrier 2 at time T2 as indicated with hatching with left down lines on the table, the number of error bits exceeds the capability of error correction at time T2 so that the communication can no longer be continued. Thus, as indicated with hatching with right down lines on the table, re-training, i.e. re-transmission of training signals, is performed in order to resume the communication by assigning a modulation scheme in accordance with the result of the re-training, that is, it is possible to convey two bits per symbol to the carriers 1 and 2 and to convey four bits per symbol to the carriers 3 and 4.

In that case, however, there is a shortcoming in that data transmission has to be halted during the re-transmission of training signals. For example, in the case where real time transmission is needed such as VoIP (Voice over Internet Protocol) for voice conversations over the Internet, this shortcoming leads to a serious problem because the voice conversation is hindered or interrupted when data transmission is hindered by the training signals.

### SUMMARY OF THE INVENTION

It is an object of the present invention to provide a communication system in which an optimal modulation scheme can be readily determined and designated for each carrier without interrupting data transmission.

In accordance with the present invention, a communication system comprises: a transmitter for adding an error correction code to first data to be transmitted to form second data, dividing the second data into data items, assigning the data items to a plurality of frequency divided carriers, modulating the data items by the respective carriers, and transmitting the modulated data on the carriers; a receiver for receiving the modulated data; a demodulator for demodulating the modulated data received by the receiver separately for the respective carriers into the data items, and reconstructing demodulated data from the data items to thereby generate the demodulated data; an error corrector for performing error correction on the demodulated data on a basis of the error correction code demodulated to generate error correction execution data; a detector for comparing the demodulated data with the error correction execution data, and determining whether or not a number of bits of the data error-corrected exceeds a predetermined tolerable value; and a notification unit for determining to which of the carriers the corrected data item is assigned, and sending a notification that an amount of data to be transmitted on the determined carrier is to be changed.

By this configuration, since error bits in the received data can be detected separately for each carrier, even when the transmission characteristics of each carrier change, the modulation scheme of the carrier can be switched to follow the change. It is also possible to continue data transmission without causing an error which cannot be corrected. For example, when the S/N ratio of a particular carrier is degraded, the modulation scheme used by the carrier is switched to a modulation scheme which can be used for data transmission even with the degraded S/N ratio so that the data transmission can be continued.

In accordance with another aspect of the present invention, a communication system comprises: a first interleave unit for adding an error correction code to first data to be transmitted, and interleaving the first data to thereby generate second data; a transmitter for dividing the second data into data items, assigning the data items to a plurality of frequency divided carriers, modulating the data items by the respective carriers, and transmitting the modulated data on the carriers; a receiver for receiving the modulated data; a demodulator for demodulating the modulated data received by the receiver separately for the respective carriers into the data items, and reconstructing and de-interleaving the demodulated data items to thereby generate demodulated data; an error corrector for performing error correction on the demodulated data on a basis of the error correction code demodulated to generate error correction execution data; a second interleave unit for interleaving the error correction execution data to generate third data; a detector for comparing the demodulated data with the third data, and determining whether or not a number of bits of the data error-corrected exceeds a predetermined tolerable value; and a notification unit for determining to which of the carriers the corrected data item is assigned, and sending a notification that an amount of data to be transmitted on the determined carrier is to be changed.

By this configuration also, even when the transmission characteristics of each carrier change, the modulation scheme of the carrier can be switched to follow the change, it is possible to continue data transmission without causing an error which cannot be corrected. For example, when the S/N ratio of a particular carrier is degraded, the modulation scheme used by the carrier is switched to a modulation scheme which can be used for data transmission even with the degraded S/N ratio so that the data transmission can be continued. In addition, by interleaving (or shuffling) the bits of the data to be transmitted after coding, any burst of bit-errors can be broken up into a set of scattered single-bit errors when the bits de-interleaved, so that the error correction ability can be improved.

In accordance with a further aspect of the present invention, a wireless multicarrier communication system for transmitting and receiving data to and from another communication system which has the same configuration as the multicarrier wireless communication system comprises: a transmitter/receiver for receiving radio waves through an antenna, converting the radio waves into an electric signal modulated by a plurality of carriers, which are modulated by respective data blocks to be received, and converting data blocks into an electric signal modulated by the plurality of carriers, which are modulated by data blocks to be transmitted, and transmitting radio waves modulated by the electric signal through the antenna, the data blocks having error correction codes added; a transmission data generator operatively connected to the transmitter/receiver and an external device for receiving data blocks to be transmitted from the external device, modulating the plurality of carriers with the data blocks, and outputting the modulated carriers to the transmitter/receiver, the transmission data generator modulating the carriers by use of different modulation schemes, the modulation schemes used by the carriers being independently switchable in response to an appropriate modulation scheme notification indicative of an optimal modulation scheme for the respective carriers transmitted from the external device; a demodulation and dividing unit operatively connected to the transmitter/receiver for receiving the electric signal from the transmitter/receiver, demodulating the electric signal, and separately outputting the carriers modulated by the data blocks; a decoder operatively connected to the demodulation and dividing unit for receiving the carriers modulated by the data blocks, and using any one of the different modulation schemes to decode the carriers to obtain the data blocks; an error detector operatively connected to the decoder for receiving the data blocks, and using the error correction codes added to the data blocks to detect a number of error bits included in the data blocks of each carrier; and an optimal modulation scheme selector operatively connected to the error detector and the transmitter/receiver for receiving information about the numbers of the error bits included in the data blocks of each carrier, and determining whether or not the modulation schemes used by the respective carriers are to be switched on the basis of the information on the number of the error bits of the respective carriers. The optimal modulation scheme selector transmits, if it is determined that the modulation scheme used by the carrier is to be switched, the appropriate modulation scheme notification indicative of an optimal modulation scheme selected from the different modulation schemes for the carrier on the basis of the determination through the transmitter/receiver to the other communication system.

The present invention provides the advantages that an optimal modulation scheme can be readily determined and that the modulation scheme can be switched without interrupting data transmission.

### BRIEF DESCRIPTION OF THE DRAWINGS

The objects and features of the present invention will become more apparent from consideration of the following detailed description taken in conjunction with the accompanying drawings in which:

FIG. 1 is a schematic diagram showing a wireless communication system in accordance with a preferred embodiment of the present invention;

FIG. 2 is a schematic diagram showing a wireless communication device in accordance with the embodiment of the present invention;

FIG. 3 is a schematic diagram showing a transmission data generator included in the wireless communication device shown in FIG. 2;

FIG. 4 is a schematic diagram showing a received data processor included in the wireless communication device shown in FIG. 2;

FIG. 5 is a flow chart useful for understanding a data transmission process routine of the wireless communication device in accordance with the embodiment;

FIGS. 6A and 6B show a data reception process routine of the wireless communication device in accordance with the embodiment;

FIG. 7 is a flow chart useful for understanding a modulation scheme switching process routine of the wireless communication device in accordance with the illustrative embodiments of the present invention;

FIG. 8 is a schematic diagram, like FIG. 3, showing a transmission data generator in accordance with an alternative embodiment of the invention;

FIG. 9 is a schematic diagram, like FIG. 4, showing a transmission data generator in accordance with the alternative embodiment;

FIG. 10 is a flow chart useful for understanding a data transmission process routine of the wireless communication device in accordance with the alternative embodiment;

FIG. 11 shows part of a data reception process routine of the wireless communication device in accordance with the alternative embodiment and continues to FIG. 6B;

FIG. 12 shows errors occurring in carriers in an example of prior art multicarrier transmission system; and

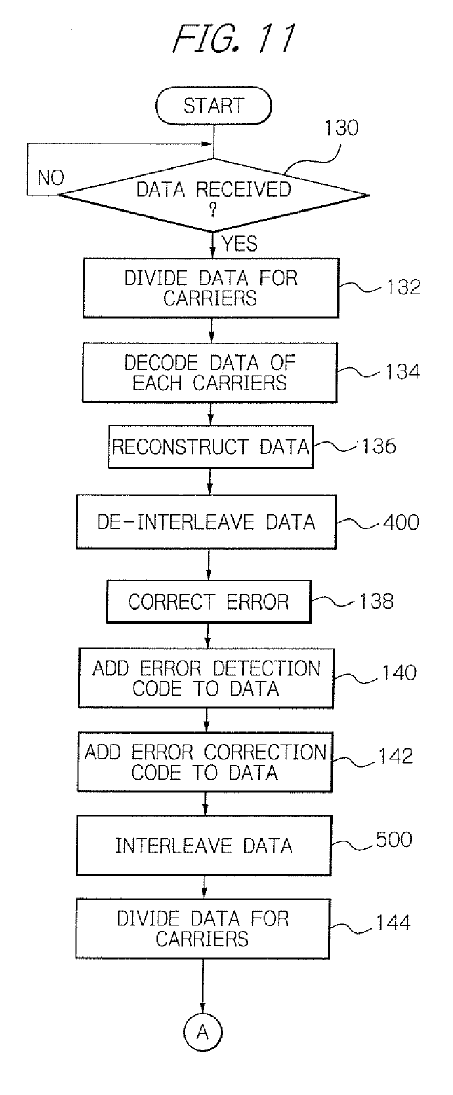

FIG. 13 shows errors occurring in carriers in the wireless communication system in accordance with the embodiment shown in FIG. 2.

### DESCRIPTION OF THE PREFERRED EMBODIMENTS

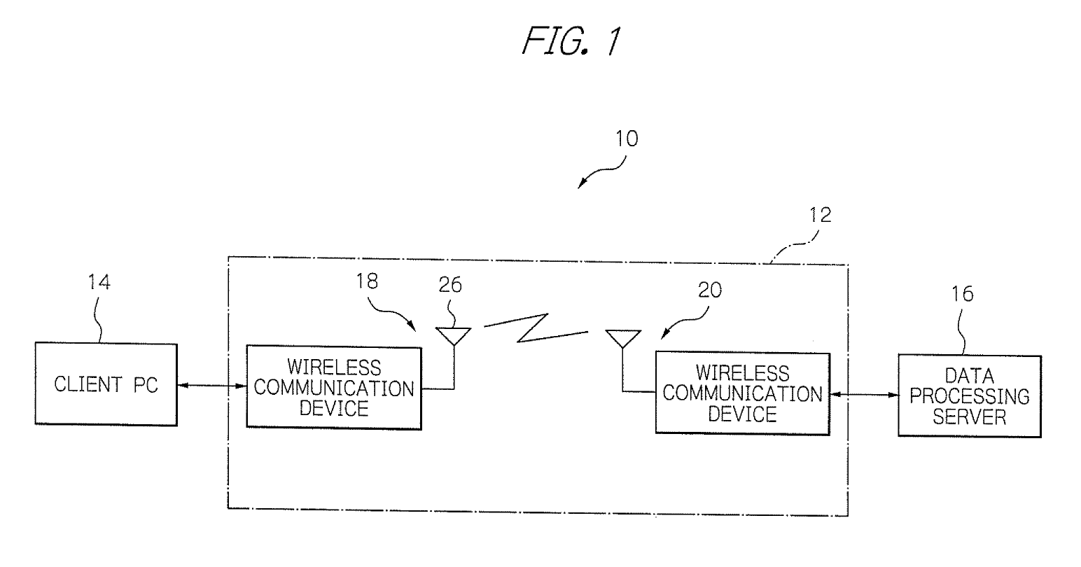

With reference to the accompanying drawings, embodiments according to the present invention will hereinafter be described in detail. First, as shown in FIG. 1, a data communication system 10 includes a wireless communication system 12 for performing a wireless data communication in accordance with an illustrative embodiment, a client personal computer (PC) 14, and a data processing server 16. The wireless communication system 12 includes wireless communication devices 18 and 20 each of which comprises a wireless LAN card, a wireless router or the like, not shown, using a plurality of carrier waves for transmitting and receiving data in accordance with modulation schemes which are selected for the respective carrier waves. The client personal computer 14 is connected to the wireless communication device 18, and the data processing server 16 is connected to the wireless communication device 20. Accordingly, the client personal computer 14 and the wireless communication device 18 can transmit and receive data from each other, and the data processing server 16 and the wireless communication device 20 can transmit and receive data from each other. The data transmission and reception between the client personal computer 14 and the data processing server 16 is performed through the wireless communication system 12.

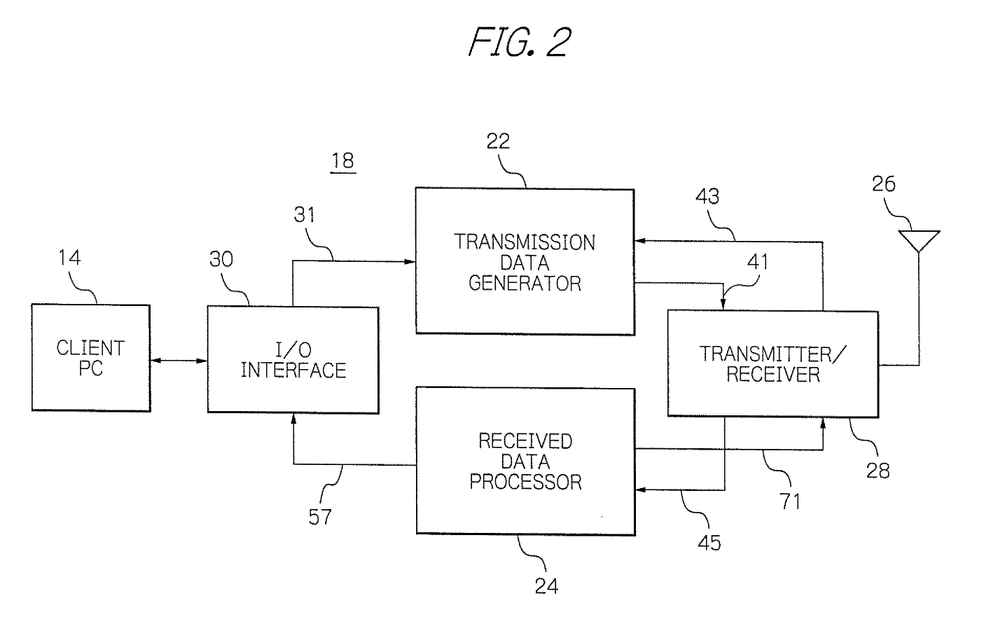

Now, the wireless communication device 20 may have the configuration similar to that of the wireless communication device 18. Description will therefore be made on the wireless communication device 18 in order not to repeat redundant description. As illustrated in FIG. 2, the wireless communication device 18 includes a transmission data generator 22 for generating data to be transmitted, a received data processor 24 for processing received data, an antenna 26 for transmitting and receiving radio waves, a transmitter/receiver 28 for receiving data by the antenna 26 to output it to the received data processor 24 and receiving the data generated by the transmission data generator 22 to transmit it in the form of modulated signal through the antenna 26, and an input/output (I/O) interface 30, which is connected to the client personal computer 14 and interfaces the transmission and reception between the client personal computer 14 and the wireless communication device 18. Thus, the transmission data generator 22, the antenna 26 and the transmitter/receiver 28 serve as a data transmission means in combination, and the received data processor 24, the antenna 26 and the transmitter/receiver 28 serve as a data reception means in combination.

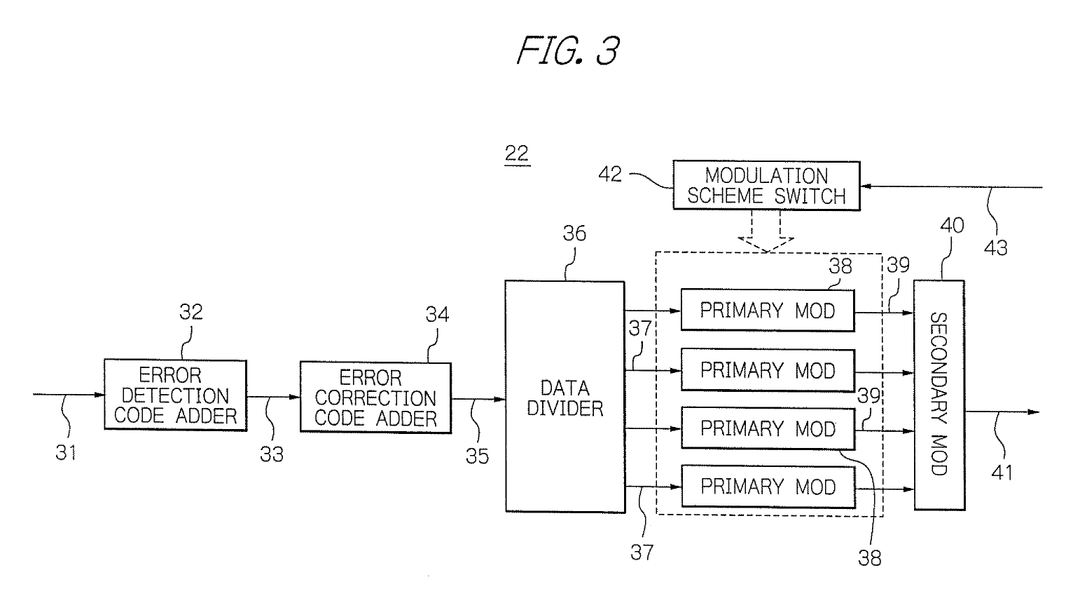

With reference to FIG. 3, the transmission data generator 22 generally includes an error detection code adder 32, an error correction code adder 34 connected to the detection code adder 32, a data divider 36 connected to the correction code adder 34, primary modulators 38 connected to the divider 36, a secondary modulator 40, and a modulation scheme switch 42. The error detection code adder 32 is adapted to receive raw data 31 as a first data block via the input/output interface 30 from the client personal computer 14, and add an error detection code, such as a cyclic redundancy check (CRC) code, to the first data block, to output the result of addition 33. Like that, signals are designated with reference numerals of connections on which they are conveyed. The error correction code adder 34 is adapted to receive the data block 33 having the error detection code added by the error detection code adder 32 as a second data block, and add an error correction code to the second data block to output the result of addition 35. The error detection code may be, for example, a Reed-Solomon code, a convolutional code or the like. The data divider 36 is adapted for receiving the second data block 35 from the error correction code adder 34, and dividing the second data block into data items 37 to dispatch the data items 37 to the respective carrier waves, and more specifically to the respective primary modulators 38.

The primary modulators 38 are provided in correspondence with the respective carriers so that each primary modulator 38 receives a data item 37 from the data divider 36 and performs primary modulation on the data items 37 to output the modulated data item 39 to the secondary modulator 40. More specifically, each of the primary modulators 38 is adapted to modulate the divided data item 37 with a modulation scheme which allows a predetermined amount of data to be transmitted as one packet on a specific carrier wave. The primary modulators 38 may be implemented with four modulation schemes of 4-PSK (Phase Shift Keying), 16-QAM, 64-QAM and 256-QAM (Quadrature Amplitude Modulation), for example.

The secondary modulator 40 is adapted to receive the data pieces 39 from the primary modulators 38 and perform secondary modulation on the data pieces 37 to output the secondary modulated data 41 to the transmitter/receiver 28. For example, the secondary modulation may include IFFT (Inverse Fast Fourier Transform), parallel-to-serial conversion, spread spectrum and so forth.

The modulation scheme switch 42 is responsive to a modulation scheme notification signal 43 which is transmitted from the wireless communication device 20 through the transmitter/receiver 28 to switch the modulation schemes for the respective carriers used in the primary modulators 38, as will be described below in detail.

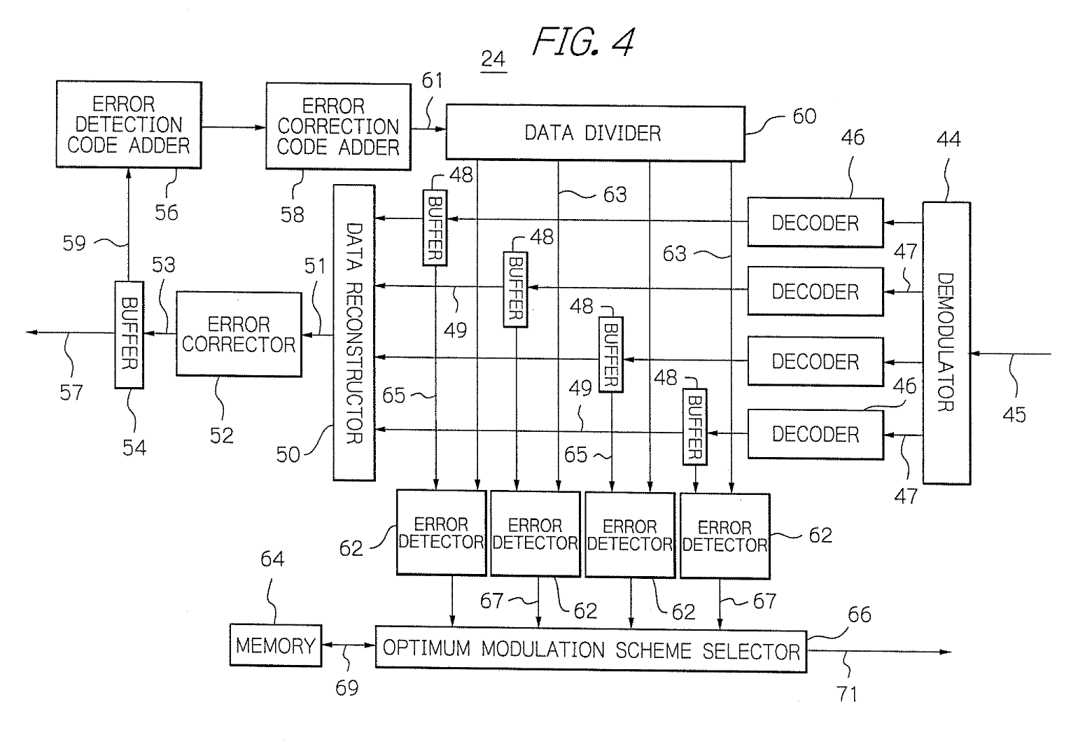

Now, with reference to FIG. 4, the received data processor 24 generally includes a demodulator 44, four decoders 46, four buffers 48, a data reconstructor 50, an error corrector 52, a buffer 54, an error detection code adder 56, an error correction code adder 58, a data divider 60, four error detectors 62, a memory 64, and an optimal modulation scheme selector 66.

The demodulator 44 is connected to the transmitter/receiver 28, and serves as a demodulation means for demodulating the data 45 which is transmitted from the wireless communication device 20 and input through the transmitter/receiver 28. The demodulator 44 is also connected to the decoders 46, and serves as a data dividing means for dividing the demodulated data 45 into data items 47 to dispatch the data items 47 for the respective carriers to the corresponding decoders 46. The data items 47 are then decoded by the decoders 46, and temporarily stored in the respective buffers 48.

The data reconstructor 50 functions as reading out the data items 49 stored in the respective buffers 48 and reconstructing a data block 51 therefrom. The error corrector 52 performs error correction on the data block 51 reconstructed by the data reconstructor 50 on the basis of the error correction code added for the respective carriers, for example by use of a Viterbi algorithm, in order to produce error corrected data 53. In the error corrector 52, the error corrected data 53 is checked in terms of error by use of the error detection code added to the data block 53. The error corrected data 53 is temporarily stored in the buffer 54 and output on one hand to the input/output interface 30 on a connection 57 and on the other hand to the error detection code adder 56 on a connection 59.

For example, the demodulator 44 is capable of processing inverse spread spectrum operation, serial-to-parallel conversion, Fast Fourier Transform (FFT) and so forth. The decoders 46 may be implemented with four modulation schemes of 4-PSK, 16-QAM, 64-QAM and 256-QAM.

In order to generate error correction execution data 61, the error detection code adder 56 and the error correction code adder 58 are provided to add an error detection code and an error correction code to the error corrected data 59 stored in the buffer 54, respectively. The error correction execution data 61 is input to the data divider 60 serving as another data dividing means for dividing the error correction execution data 61 into data items 63 for the respective carriers, which are then input to the respective error detectors 62.

The error detectors 62 function as comparing the respective data items 63 input from the data divider 60 with the respective data items 65 transferred from the buffers 48 to determine, for each carrier, whether or not the number of the error corrected data exceeds a predetermined tolerable value, or threshold, on the basis of the result of comparison. In other words, the error detectors 62 serve as a detection means for detecting the occurrence of an unsafe error when the number of data corrected by the error corrector 52 exceeds the predetermined tolerable value. The optimal modulation scheme selector 66 is adapted to receive the information 67 on the unsafe error to count the number of unsafe errors which occur in a predetermined period for each carrier. The memory 64 is used to store data 69 indicative of a plurality of modulation schemes different in transmission data quantity from each other.

The optimal modulation scheme selector 66 serves as integrating errors for a carrier, when detected in the error detector 62, e.g. when the number of unsafe errors of a carrier as counted exceeds the predetermined value, over a given period, and extract, on the basis of the result of integration, the data indicative of an appropriate modulation scheme which can be used to continue communication by this carrier without causing an error which cannot be corrected to output the data 71 to the transmitter/receiver 28. The data 71 indicative of the new appropriate modulation scheme is transmitted to the wireless communication device 20 through the transmitter/receiver 28 and the antenna 26. This data is received by the wireless communication device 20, which may be similar in construction to the communication device 18.

In the communication device 20, the modulation scheme switch 42 is responsive to the data 43 thus received to switch for the corresponding carrier this appropriate modulation scheme, which has a smaller number of bits per symbol than the modulation scheme currently used by this carrier. Conversely, when the number of unsafe errors of a carrier as counted does not exceed the predetermined value, the current modulation scheme is not switched to continue communication as before. The optimal modulation scheme selector 66, the transmitter/receiver 28 and the antenna 26 thus serve as a notification means for notifying the switching of the current modulation scheme to an optimal modulation scheme.

In addition to the functions as described above, the optimal modulation scheme selector 66 has the function of monitoring whether or not no error bit is detected of a carrier by the error detectors 62 over a predetermined period, and extracting from the memory 64 the data indicative of a modulation scheme having a data conveying capability one step higher than the modulation scheme which is currently used by this carrier when an error is not detected by the error detectors 62 during the predetermined period. The optimal modulation scheme selector 66 also outputs this data 71 to the transmitter/receiver 28. For example, in the case where the memory 64 stores the data indicative of a modulation scheme A, a modulation scheme B having a data conveying capability higher than the modulation scheme A and a modulation scheme C having a data conveying capability higher than the modulation scheme B, if the modulation scheme A is used by a certain carrier, when no error bit is detected of this carrier by the error detector 62 over the predetermined period, the optimal modulation scheme selector 66 extracts the data indicative of a modulation scheme having a data conveying capability one step higher than the modulation scheme A, i.e. by selecting the modulation scheme B.

The wireless communication device 12 may include a microcomputer, not shown, including a CPU (Central Processor Unit), a RAM (Random Access Memory), a ROM (Read-Only Memory) and the like. The above described functions and units in the device 12 may be implemented by software modules, which are stored as parts of program sequences or applications stored in the ROM and run by the CPU. These software modules may be run as a data transmission process routine, a data reception process routine and a modulation scheme switching process routine. However, the primary modulators 38, the secondary modulator 40, the demodulator 44 and the decoders 46 may advantageously be implemented in the form of dedicated circuits for the purpose of speeding up the processes. The buffers 48 and 54 may be implemented as storage areas of the RAM.

Since the wireless communication device 20 may have the similar configuration to the wireless communication device 18, the wireless communication device 18 will mainly be described in order not to repeat redundant description. The input/output interface 30 of the wireless communication device 20 is connected to the data processing server 16.

Meanwhile, the client personal computer 14 may be a commonly used personal computer having a popular configuration, and the data processing server 16 may be a commonly used server computer also having a popular configuration. Accordingly, in the present embodiment, the description of the general operation of the client personal computer 14 and data processing server 16 is dispensed with.

Now, the operation of the wireless communication device 12 will be described on an example of transmitting data from the client personal computer 14 to the data processing server 16 through the wireless communication system 12.

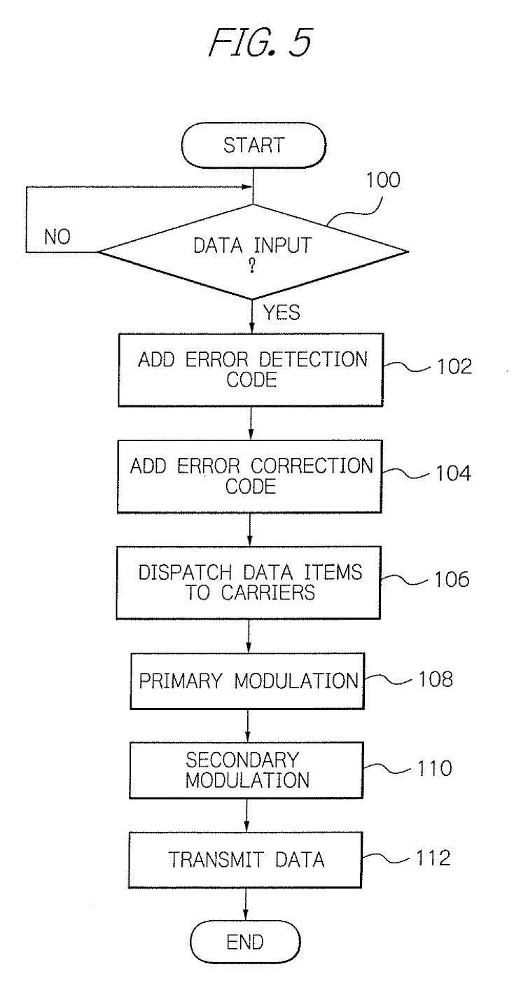

When the user instructs the client personal computer 14 to transmit data to the data processing server 16, the personal computer 14 inputs data to the wireless communication device 18, which in turn runs the data transmission process routine as illustrated in FIG. 5.

First, in step 100, it is determined whether or not a first data block is input from the client personal computer 14. If the first data block 31 is input, the process proceeds from step 100 to step 102 in which an error correction code is added to the first data block, and otherwise repeats the same step 100. Furthermore, in step 104, an error correction code is added to the first data block. The first data block to which the error detection and correction codes are added is referred to as a second data block.

In step 106, the second data block 35 is divided into data items 37 and dispatched to the primary modulators 38 for the respective carriers. The data items are primary modulated in step 108 and secondary modulated in step 110. Then, in step 112, the data items are transmitted to the wireless communication device 20.

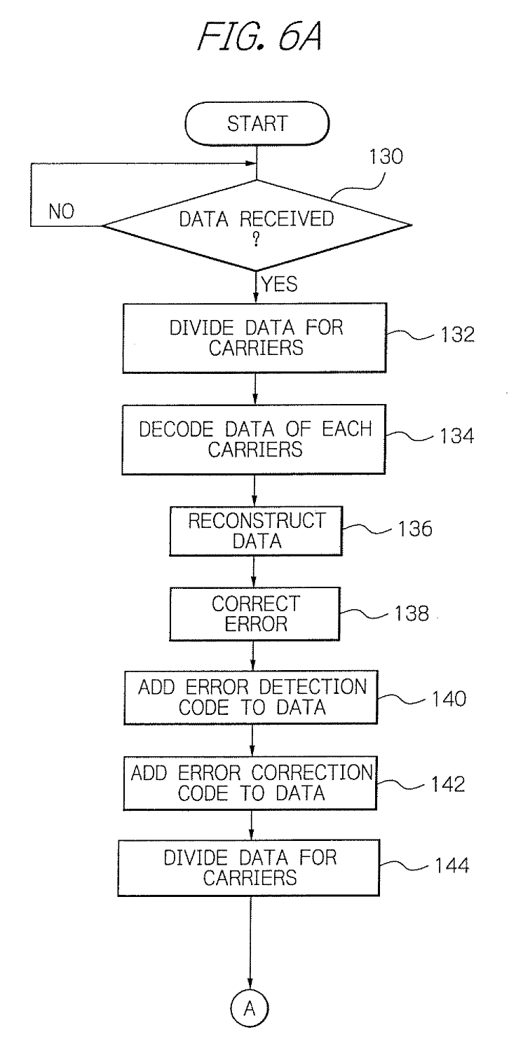

Next, the data reception process routine performed by the wireless communication device 20 will be described with reference to FIGS. 6A and 6B. It is determined in step 130 whether or not data is received from the wireless communication device 18. If data is received, the process proceeds from step 130 to step 132 in which the received data 45 is divided into data items 47 for each carrier, and otherwise repeats the same step 130. In step 134, the data items 47 are decoded for each carrier. The data items as decoded are stored in the buffers 48. The buffers 48 have storage capacity for storing at least one block of data.

In step 136, the data items of the respective carriers stored in the buffers 48 are reconstructed. In step 138, the error correction process is performed on the data block obtained by the reconstruction. The data block 53 thus error corrected is stored in the buffer 54.

In step 140, the data block stored in the buffer 54 is extracted, and thereafter an error detection code is added to the data block 59. In step 142, an error correction code is added to the data block. In step 144, the data block 61 to which the error detection and correction codes are added is divided into data items 63 and dispatched to the error detectors 62 by assigning the data items to the respective carriers. Then, the data items 63 as dispatched in step 144 are compared with the data items 65 which are decoded in step 134, error corrected in step 138 and stored in the buffers 48. The process in turn proceeds from step 146 to step 148.

It is determined by the error detectors 62 in step 148 whether or not an error bit is detected of the data item to be conveyed by each carrier on the basis of the result of comparison in step 146. If an error bit is detected, the process proceeds from step 148 to step 150. The method of detecting an error bit for each carrier may be based on the estimation of whether or not the S/N ratio of each carrier is degraded by detecting a change in BER (Bit Error Rate) for each carrier, for example.

The optimal modulation scheme selector 66 extracts from the memory 64 the data 69 indicative of a modulation scheme which can be used to continue communication without causing an error which cannot be corrected in step 150, and transmits the data 71 to the wireless communication device 18 in step 152.

For example, in the case where the memory 64 stores five data pieces indicative of the modulation schemes A to E, it is assumed that error occurs in the data of the carrier A which is transmitted from the wireless communication device 18 to the wireless communication device 20 in accordance with the modulation scheme A, and that the modulation scheme C can be used in this situation to continue communication without causing an error which cannot be corrected. In this situation, the optimal modulation scheme selector 66 fetches from the memory 64 the data indicative of the modulation scheme C, and transmits the data to the wireless communication device 18.

It is to be noted that, if it is said that an alternative modulation scheme can be used to continue communication without causing an error which cannot be corrected, this alternative modulation scheme is the best possible modulation scheme for the current communication environment in which the S/N ratio is degraded. Meanwhile, for example, such an alternative modulation scheme can be selected by estimating an optimal modulation scheme on the basis of the pattern and number of an error bit or bits detected by the error detector 62.

Well, if it is determined in step 148 that there is no error in the data of a carrier, then the process proceeds from step 148 to step 154 in which it is determined whether or not no error bit is detected of this carrier by the error detector 62 during the predetermined period. If an error bit is detected in the predetermined period in step 154, the data reception process routine ends. Conversely, if no error bit is detected of this carrier over the predetermined period in step 154, the data indicative of a modulation scheme having a data conveying capability one step higher than the modulation scheme which is currently used is extracted from the memory 64 in step 156, and the data is transmitted to the wireless communication device 18 in step 152.

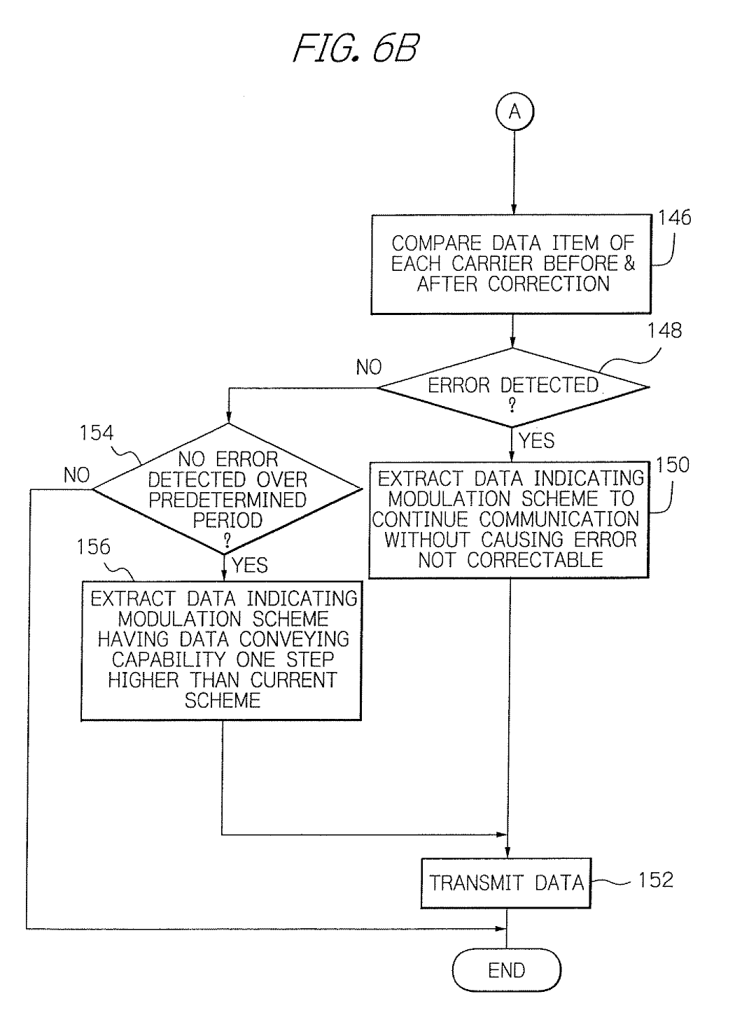

Next, when the wireless communication device 18 receives the data transmitted from the wireless communication device 20 in step 152, the wireless communication device 18 runs the modulation scheme switching process routine as shown in FIG. 7. In step 180, it is determined whether or not the wireless communication device 18 receives the data transmitted from the wireless communication device 20 in step 152. If the data is received, the wireless communication device 18 switches the modulation scheme of the carrier corresponding to the data in the primary modulator 38 in step 182, otherwise repeats the same step 180.

For example, in the case where there are four carriers A to D and three modulation schemes A, B and C and one of the primary modulators 38 which is currently used by the carrier A is set to the modulation scheme B, when an error occurs in the data of the carrier A, the wireless communication device 20 transmits the data indicative of the modulation scheme C. Then, in the wireless communication device 18 having received the data, the modulation scheme switch 42 switches the modulation scheme of the primary modulator 38 corresponding to the carrier A from the modulation scheme B to the modulation scheme C. Needless to say, when the modulation scheme of this primary modulator 38 is switched from the modulation scheme B to the modulation scheme C, the data conveying capability per carrier unit (for example, symbol) is decreased. The data transmission accuracy is improved by this switching.

As has been discussed above, in accordance with the wireless communication system of the illustrative embodiment, it is possible to perform error correction on the entire data and error detection of each carrier on the basis of the result of the error correction of the entire data. Furthermore, it is possible to select an optimal modulation scheme for each carrier on the basis of the error detection result, and to continue data transmission without causing an error which cannot be corrected because, even when the transmission characteristic, e.g. S/N ratio, of each carrier dynamically changes, since the modulation scheme of each carrier is dynamically switched to follow the change.

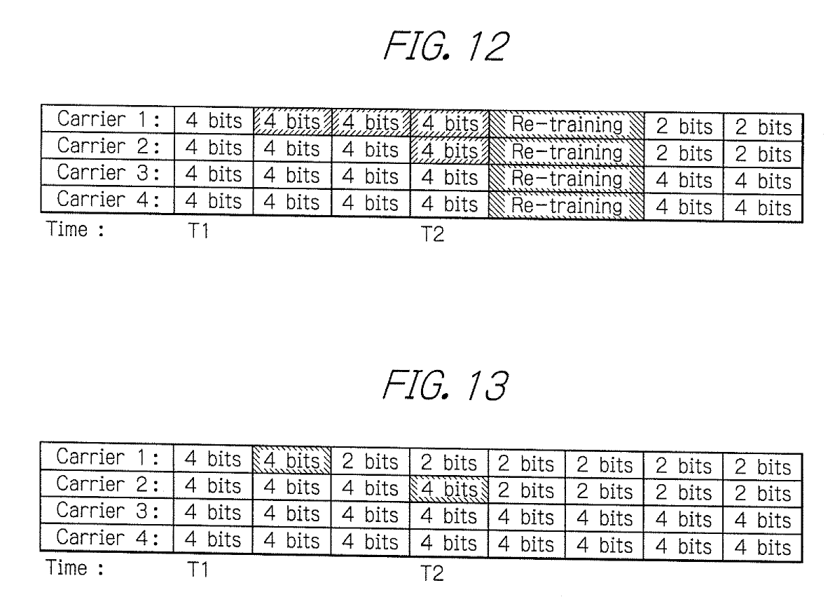

For example, it is considered that carriers 1, 2, 3 and 4 are used to perform communication of 4-bit/carrier (4 bits per symbol) in which up to 4 bits of 16-bit data can be corrected by error correction. In such a case, when an error occurs in the carrier 1 at time T1 as indicated by hatching with right down lines on a table shown in FIG. 13, it is detected by the error detector 62 and the optimal modulation scheme selector 66 that the S/N ratio of the carrier 1 is degraded at time T1, and the modulation scheme for the carrier 1 is switched to an appropriate modulation scheme corresponding to the degraded S/N ratio, i.e. a modulation scheme being suitable for communication of 2 bits per symbol. Also, when an error occurs in the carrier 2 at time T2 in the same situation also as indicated by hatching with right down lines on the table shown, it is detected by the error detector 62 and the optimal modulation scheme selector 66 that the S/N ratio of the carrier 2 is degraded at time T2, and the modulation scheme for the carrier 2 is switched to an appropriate modulation scheme corresponding to the degraded S/N ratio, i.e. a modulation scheme being suitable for communication of 2 bits per symbol. By this process, it is possible to continue data transmission even when the S/N ratio is degraded.

The present invention is particularly effective to systems where there is a substantial difference in characteristics between carriers and the characteristics tend to dynamically change, such as xDSL (Digital Subscriber Line) or BPL (Broadband over Power Line) systems.

In the case of above illustrative embodiment, when no error bit is detected of a particular carrier by the error detector 62 over a predetermined period, the data indicative of a modulation scheme having a data conveying capability one step higher than the modulation scheme which is currently used is extracted from the memory 64 by the optimal modulation scheme selector 66 in step 156. However, when no error bit is detected of a particular carrier over the predetermined period, the optimal modulation scheme selector 66 also may extract from the memory 64 a modulation scheme having a data conveying capability two or more steps higher than the modulation scheme which is currently used.

For example, a case is assumed where there are three modulation schemes A, B and C and one of the primary modulators 38 which is currently used by a particular carrier is set to the modulation scheme A while the modulation scheme C has a data conveying capability higher than the modulation scheme B which in turn has a data conveying capability higher than the modulation scheme A. In this situation, when no error bit is detected of the particular carrier by the error detector 62 over the predetermined period, the optimal modulation scheme selector 66 may extract from the memory 64 the data indicative of a modulation scheme having a data conveying capability two steps higher than the modulation scheme A, i.e. by selecting the modulation scheme C. By this, a larger amount of data can be transmitted.

While only the carriers which can be used for data transmission are used in the case of above illustrative embodiment, it is also possible to make effective use of a carrier which is unfit for data transmission. In this case, even when the S/N ratio of a particular carrier is too low to be used for data transmission to the wireless communication device 20, the wireless communication device 18 continues transmitting a predetermined pilot data piece by the modulation scheme having the lowest data conveying capability, i.e. the modulation scheme with a lowest probability of causing an error, to the wireless communication device 20. Then, in the wireless communication device 20, the modulation scheme with a lowest probability of causing an error is used to perform modulation for a carrier without transmitting data. When it is confirmed on the basis of the result of the modulation that the transmission of the predetermined pilot data piece becomes successful, the wireless communication device 20 notifies the wireless communication device 18 that the carrier can be used for data transmission. In response to the notification, the wireless communication device 18 makes use of the carrier for data transmission. By this process, the carrier which is unfit for data transmission is monitored, and the data transmission by this carrier can be resumed as soon as it becomes possible when the S/N ratio is improved.

Meanwhile, there is a prior art multicarrier transmission technique to dynamically switch the modulation scheme of each carrier during data transmission by processing the data transmission process (and data reception process) separately for each carrier and acquiring error information from each carrier. However, in this conventional approach, it is necessary to wait for the transmission until a predetermined amount of data becomes available for adding error correction and detection codes thereto such as a CRC (Cyclic Redundancy Check) code, and thereby the transmission delay substantially increases. This shortcoming leads to a serious problem, for example, in an application in which real time transmission of a small amount of data is needed such as VoIP. However, according to the system of the invention, a data block to be processed by error detection and correction is divided into a plurality of data items which are transmitted by a plurality of carriers of a channel, and thereby the transmission delay can be minimized.

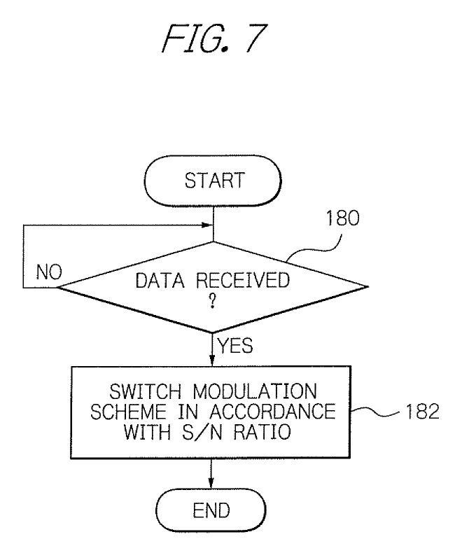

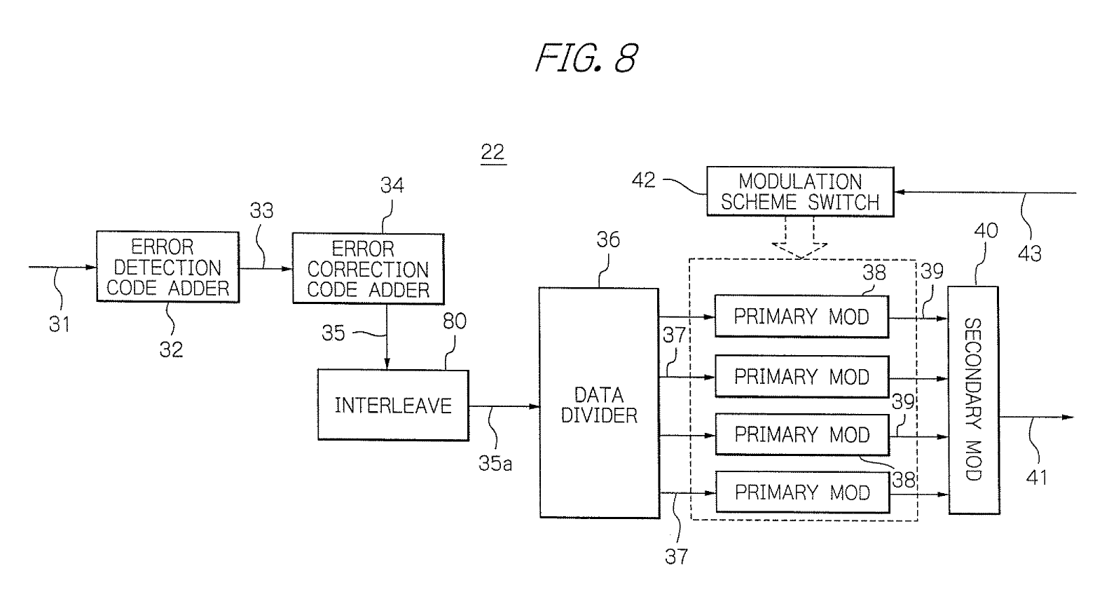

Well, an alternative embodiment of the present invention will be described with reference to FIGS. 8 and 9. In the description, like components are designated with the same reference numerals, and no redundant description is repeated.

Particularly, as shown in FIGS. 8 and 9, in the wireless communication device 18, the transmission data generator 22 additionally includes an interleave unit 80 interconnected between the error correction code adder 34 and the data divider 36. The received data processor 24 also additionally includes an interleave unit 84 interconnected between the error correction code adder 58 and the data divider 60, and a de-interleave unit 82 interconnected between the data reconstructor 50 and the error corrector 52. The alternative embodiment may be the same as the illustrative embodiment shown in and described with reference to FIGS. 3 and 4 except for the provision of the interleave units 80 and 84 and the de-interleave unit 82.

In the same manner as in the embodiment shown in FIGS. 3 and 4, the error detection code adder 32 and the error correction code adder 34 add error detection and error correction codes, respectively, to a data block 31 which is input from the client personal computer 14 through the input/output interface 30. The interleave unit 80 receives the first data block 35 from the error correction code adder 34, and interleaves the first data block to output the interleaved first data block as second data block 35a to the data divider 36. The second data block 35a is then divided by the data divider 36, modulated by the primary modulators 38 and transmitted through the transmitter/receiver 28 and the antenna 26 in the same manner as in the embodiment shown in FIG. 3.

With reference to FIG. 9, when the received data processor 24 receives data from the transmission data generator 318, the data 45 is input to the demodulator 44, decoded by the decoders 46, saved by the buffers 48, and reconstructed by the data reconstructor 50 into the interleaved data block 51.

The de-interleave unit 82 receives the interleaved data block 51 from the data reconstructor 50 to de-interleave the interleaved data block 51. The de-interleaved data block 51a is then error corrected by the error corrector 52 and stored in the buffer 54. In the same manner as in the embodiment shown in FIG. 4, the data block 59 stored in the buffer 54 is transferred to the error detection code adder 56 and the client personal computer 14 through the input/output interface 30. Moreover, in the error detection code adder 56 and the error correction code adder 58, error detection and correction codes are respectively added to the de-interleaved data block 59. The interleave unit 84 interleaves the data block 61 with the error detection codes and error correction codes received from the error correction code adder 58 to output the interleaved data block as a third data block 61a to the data divider 60, which in turn divides and dispatches the third data to the error detectors 62. The remaining functional blocks may be equivalent to those of the embodiment shown in FIGS. 3 and 4, and therefore no redundant description is repeated.

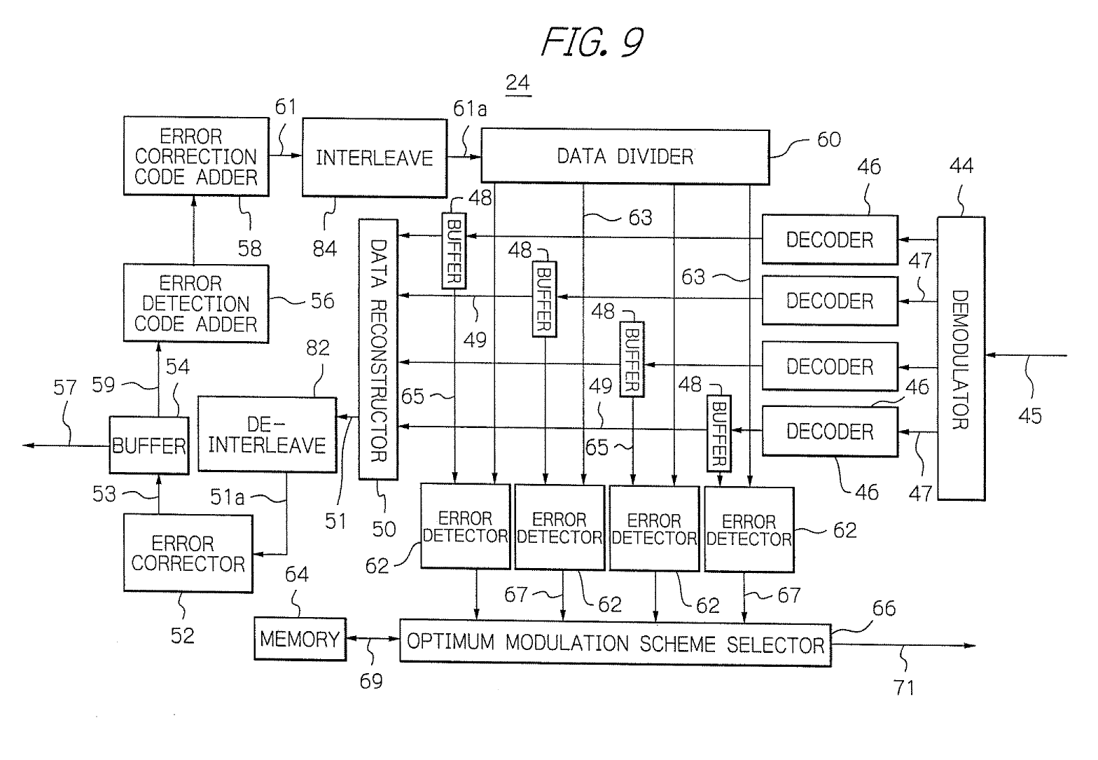

Now, the data transmission process routine of the wireless communication device 18 will be described with further reference to FIG. 10. First, it is determined whether or not a first data block is input from the personal computer 14 in step 100, an error correction code is added to the first data block in step 102, and an error correction code is added to the first data block in step 104. Particularly, in this alternative embodiment, step 300 of interleaving data items is introduced. After adding error detection and correction codes in steps 102 and 104, two data blocks are interleaved in step 300. The data items thus interleaved are then divided by the data divider 36 in step 106, modulated by the primary modulators 38 and secondary modulator 40 in steps 108 and 110 and transmitted through the transmitter/receiver 28 and the antenna 26 to the other wireless communication device 20 in step 112 in the same manner as the illustrative embodiment described earlier with reference to FIG. 5.

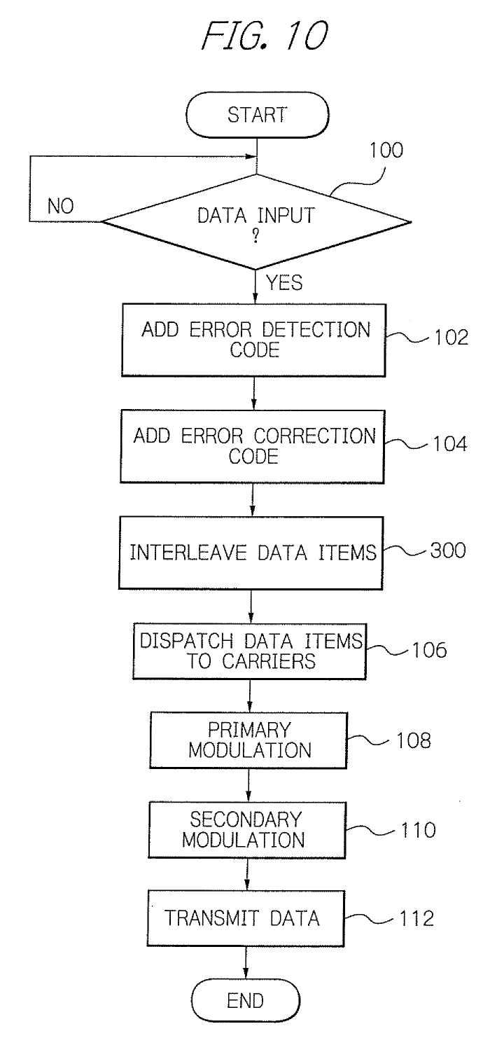

Next, the data reception process routine which is run in the wireless communication device 20 will be described with reference to FIG. 11. It is determined in step 130 whether or not data is received from the wireless communication device 18. If data is received, the process proceeds from step 130 to step 132 in which the received data 45 is divided into data items 47 for each carrier, and otherwise repeats the same step 130. In step 134, the data items 47 are decoded for each carrier. The data items as decoded are stored in the buffers 48. The buffers 48 are adapted to have the storage capacity of storing at least two blocks of data with the alternative embodiment.

In step 136, the data items 49 of the respective carriers stored in the buffers 48 are reconstructed. In step 400, the data 51 as reconstructed corresponding to two blocks is de-interleaved into the two blocks of data 51a. In step 138, the error correction process is performed on each of the data blocks. The data blocks 53 which are error corrected are stored in the buffer 54.

In step 140, the data blocks stored in the buffer 54 is extracted, and thereafter an error detection code is added to each of the data blocks. In step 142, an error correction code is added to each of the data blocks. In step 500, the data blocks 61 to which the error detection codes and error correction codes are added are interleaved, divided into data items and dispatched to the error detectors 62 by assigning the data items to the carriers respectively. Then, for the respective carriers, the data items 63 thus dispatched in step 144 are compared with the data items 65 which are decoded in step 134, error corrected in step 138 and stored in the buffers 48, and the process proceeds from step 146 to step 148, FIG. 6B, through the connector A.

It is determined by the error detectors 62 in step 148 whether or not an error bit is detected of the data item 63 to be conveyed by each carrier on the basis of the result of comparison in step 146, and if an error bit is detected the process proceeds from step 148 to step 150. The optimal modulation scheme selector 66 extracts from the memory 64 the data 69 indicative of a modulation scheme which can be used to continue communication without causing an error which cannot be corrected in step 150, and transmits the data 71 to the wireless communication device 18 in step 152.

Conversely, if it is determined in step 148 that there is no error in the data of a carrier, then the process proceeds from step 148 to step 154 in which it is determined whether or not no error bit is detected of this current carrier by the error detector 62 over the predetermined period. If an error bit is detected in the predetermined period in step 154, the data reception process routine ends. If no error bit is detected of this carrier over the predetermined period in step 154, then the data indicative of a modulation scheme having a data conveying capability one step higher than the modulation scheme which is currently used is extracted from the memory 64 in step 156, and the data 71 is transmitted to the wireless communication device 18 in step 152.

Next, when the wireless communication device 18 receives the data transmitted from the wireless communication device 20 in step 152, the wireless communication device 18 runs the modulation scheme switching process routine as shown in FIG. 7. In step 180, it is determined whether or not the wireless communication device 18 receives the data transmitted from the wireless communication device 20 in step 152, and if the data is received, the wireless communication device 18 switches the modulation scheme of the carrier corresponding to the data in the primary modulator 38 in step 182 to end the modulation scheme switching process routine, and otherwise repeats the same step 180.

As has been discussed above, in accordance with the wireless communication system of the alternative embodiment, there are the similar advantages to those of the wireless communication system of the embodiment shown in and described with reference to FIGS. 3 and 4. In addition, the interleave is carried out on data to thereby deal with burst errors as random errors so that the error correction capability can be improved. The communication environment can thereby be more effectively evaluated to appropriately change the modulation scheme for each carrier.

Now, a specific example will be described. The wireless communication device 18 transmits 100-bit data on a 100 Hz carrier to the wireless communication device 20. The error detector 62 of the wireless communication device 20 detects an error of the data as transmitted. The optimal modulation scheme selector 66 of the wireless communication device 20 reads out from the memory 64 the data indicative of an alternative modulation scheme suitable for an error type detected by the error detector 62, i.e. for a carrier in which the S/N ratio is degraded. For instance, the optimal modulation scheme selector 66 reads out the data indicative of the modulation scheme suitable for transmitting 50-bit data on the 100 Hz carrier, and transmits the data to the wireless communication device 18. The wireless communication device 18 receives the data indicative of the alternative modulation scheme, e.g. the modulation scheme suitable for transmitting 50-bit data on the 100 Hz carrier, and switches the modulation scheme in the primary modulator 38 to the alternative modulation, the modulation being suitable for transmitting 50-bit data on the 100 Hz carrier, corresponding to the data. Since the rate of data transmission of the carrier is reduced by this process, it is possible to improve the accuracy of data transmission from that time.

The entire disclosure of Japanese patent application No. 2006-319202 filed on Nov. 27, 2006, including the specification, claims, accompanying drawings and abstract of the disclosure, is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. A communication system comprising:
a transmitter for adding an error correction code to first data to be transmitted to form second data, dividing the second data into data items, assigning the data items to a plurality of frequency divided carriers, modulating the data items by the respective carriers, and transmitting the modulated data on the carriers;
a receiver for receiving the modulated data;
a demodulator for demodulating the modulated data received by said receiver separately for the respective carriers into the data items, and reconstructing demodulated data from the data items to thereby generate the demodulated data;
an error corrector for performing error correction on the demodulated data on a basis of the error correction code demodulated to generate error correction execution data;
a detector for comparing the demodulated data with the error correction execution data, and determining whether or not a number of bits of the data error-corrected exceeds a predetermined tolerable value; and
a notification unit for determining to which of the carriers the corrected data item is assigned, and sending a notification that an amount of data to be transmitted on the determined carrier is to be changed.

2. The communication system in accordance with claim 1, further comprising:
a first data divider for dividing the demodulated data into the data items for the respective carriers; and
a second data divider for dividing the error correction execution data into the data items for the respective carriers,
said detector comparing the data items divided by said first data divider with the data items divided by said second data divider, and determining whether or not the number of bits of the data corrected by said error corrector exceeds the predetermined tolerable value.

3. A communication system comprising:
a first interleave unit for adding an error correction code to first data to be transmitted, and interleaving the first data to thereby generate second data;
a transmitter for dividing the second data into data items, assigning the data items to a plurality of frequency divided carriers, modulating the data items by the respective carriers, and transmitting the modulated data on the carriers;
a receiver for receiving the modulated data;
a demodulator for demodulating the modulated data received by said receiver separately for the respective carriers into the data items, and reconstructing and de-interleaving the demodulated data items to thereby generate demodulated data;
an error corrector for performing error correction on the demodulated data on a basis of the error correction code demodulated to generate error correction execution data;
a second interleave unit for interleaving the error correction execution data to generate third data;
a detector for comparing the demodulated data with the third data, and determining whether or not a number of bits of the data error-corrected exceeds a predetermined tolerable value; and
a notification unit for determining to which of the carriers the corrected data item is assigned, and sending a notification that an amount of data to be transmitted on the determined carrier is to be changed.

4. The communication system in accordance with claim 3, further comprising:
a first data divider for dividing the demodulated data into the data items for the respective carriers; and
a second data divider for dividing the third data into the data items for the respective carriers,
said detector comparing the data items divided by said first data divider with the data items divided by said second data divider, and determining whether or not the number of bits of data corrected by said error corrector exceeds the predetermined tolerable value.

5. A wireless multicarrier communication system for transmitting and receiving data to and from another communication system which has a same configuration as said multicarrier wireless communication system, comprising:
a transmitter/receiver for receiving radio waves through an antenna, converting the radio waves into an electric signal modulated by a plurality of carriers, which are modulated by respective data blocks to be received, and converting data blocks into an electric signal modulated by the plurality of carriers, which are modulated by data blocks to be transmitted, and transmitting radio waves modulated by the electric signal through the antenna, the data blocks having error correction codes added;
a transmission data generator operatively connected to said transmitter/receiver and an external device for receiving data blocks to be transmitted from the external device, modulating the plurality of carriers with the data blocks, and outputting the modulated carriers to said transmitter/receiver,
said transmission data generator modulating the carriers by use of different modulation schemes, the modulation schemes used by the carriers being independently switchable in response to an appropriate modulation scheme notification indicative of an optimal modulation scheme for the respective carriers transmitted from the external device;
a demodulation and dividing unit operatively connected to said transmitter/receiver for receiving the electric signal from said transmitter/receiver, demodulating the electric signal, and separately outputting the carriers modulated by the data blocks;
a decoder operatively connected to said demodulation and dividing unit for receiving the carriers modulated by the data blocks, and using any one of the different modulation schemes to decode the carriers to obtain the data blocks;
an error detector operatively connected to said decoder for receiving the data blocks, and using the error correction codes added to the data blocks to detect a number of error bits included in the data blocks of each carrier; and
an optimal modulation scheme selector operatively connected to said error detector and said transmitter/receiver for receiving information about the numbers of the error bits included in the data blocks of each carrier, and determining whether or not the modulation schemes used by the respective carriers are to be switched on the basis of the information on the number of the error bits of the respective carriers,
said optimal modulation scheme selector transmitting, if it is determined that the modulation scheme used by the carrier is to be switched, the appropriate modulation scheme notification indicative of an optimal modulation scheme selected from the different modulation schemes for the carrier on the basis of the determination through said transmitter/receiver to the other communication system.

6. The multicarrier communication system in accordance with claim 5, wherein the plurality of carriers are provided in accordance with the OFDM (Orthogonal Frequency Division Multiplexing) technique.

7. The multicarrier communication system in accordance with claim 5, wherein the modulation schemes include a quadrature amplitude modulation scheme.

8. The multicarrier communication system in accordance with claim 5, wherein the error correction code is a convolutional code or a block code.

9. A wireless multicarrier communication system for transmitting and receiving data by use of a plurality of carriers, comprising a data transmitter, a data receiver and a transmitter/receiver connected to said data transmitter and said data receiver for transmitting and receiving data, said data transmitter comprising:
a first error correction code adder for receiving a data block to be transmitted, and adding an error correction code to the data block;
a first data divider operatively connected to said first error correction code adder for receiving the data block to which the error correction code is added, dividing the data block into first data items, and assigning the first data items to the respective carriers;
a primary modulator operatively connected to said first data divider for receiving the first data items, and modulating each carrier with one of the first data items assigned to the carrier by use of one of modulation schemes which is switchable in response to an appropriate modulation scheme notification which is instructive to effectively switch the modulation scheme and transmitted from a receiver communication system which has a same configuration as said multicarrier wireless communication system; and
a secondary modulator operatively connected to said primary modulator for receiving the modulated first data items, and modulating the modulated first data items for transmission to the receiver communication system through said transmitter/receiver,
said data receiver comprising:
a demodulator operatively connected to said transmitter/receiver for receiving an input signal including a data block from a transmitter communication system, which has the same configuration as said multicarrier wireless communication system, through said transmitter/receiver, demodulating the input signal in a form of second data items corresponding to the respective carriers, and assigning the second data items to the respective carriers;
a decoder operatively connected to said divider for receiving the second data items, and decoding the second data items by use of the modulation schemes which are used for modulating the respective carriers;
a buffer operatively connected to said decoder for receiving and storing the second data items decoded by said decoder;
a data reconstructor operatively connected to said decoder for receiving the decoded second data items and reconstructing the data block from the decoded second data items;
an error corrector operatively connected to said data reconstructor for receiving the data block and correcting an error bit contained in the data block on the basis of an error correction code added to the data block;
a second error correction code adder operatively connected to said error corrector for receiving the error corrected data block, and adding an error correction code to the error corrected data block;
a second data divider operatively connected to said second error correction code adder for receiving the data block to which the error correction code is added, dividing the received data block into third data items, and assigning the third data items to the respective carriers;
an error detector operatively connected to said second data divider and said buffer for receiving the third data items from said second data divider and the decoded second data items from said buffer, and comparing the decoded second data items with the third data items to detect a number of the corrected error bits which are contained in the third data items and assigned to each carrier; and
an optimal modulation scheme selector operatively connected to said error detector and said transmitter/receiver for receiving information about the number of the corrected error bits, and determining whether or not the modulation scheme used by each carrier is to be switched on the basis of the information on the number of the corrected error bits of the carrier,
said optimal modulation scheme selector transmitting, if it is determined that the modulation scheme used by one of the carriers is to be switched, the appropriate modulation scheme notification indicative of an optimal modulation scheme on the basis of the determination through said transmitter/receiver to said transmitter communication system.

10. The multicarrier communication system in accordance with claim 9, wherein said data reconstructor is connected to said decoder through said buffer and receives the decoded second data items from said buffer.

11. The multicarrier communication system in accordance with claim 9, wherein, when the information on the number of the corrected error bits of one of the carriers indicates that the bit error rate has increased, the modulation scheme used by the one carrier is switched to a modulation scheme having a lower data conveying capability.

12. The multicarrier communication system in accordance with claim 9, wherein, when the information on the number of the corrected error bits of one of the carriers indicates that the bit error rate has decreased, the modulation scheme used by the one carrier is switched to a modulation scheme having a higher data conveying capability.

13. A wireless multicarrier communication system for transmitting and receiving data by use of a plurality of carriers, comprising a data transmitter, a data receiver and a transmitter/receiver connected to said data transmitter and said data receiver for transmitting and receiving data,
said data transmitter comprising:
a first error correction code adder for receiving data blocks to be transmitted, and adding an error correction code to the data blocks;
a first interleave unit operatively connected to said first error correction code adder for receiving and interleaving the data blocks to which the error correction codes are added;
a first data divider operatively connected to said first interleave unit for receiving the data blocks which are interleaved, dividing the received data blocks into first data items, and assigning the first data items to the respective carriers;
a primary modulator operatively connected to said first data divider for receiving the first data items and modulating each carrier with one of the first data items assigned to the carrier by use of one of modulation schemes which is switchable in response to an appropriate modulation scheme notification which is instructive to effectively switch the modulation scheme and transmitted from a receiver communication system which has a same configuration as said multicarrier wireless communication system; and
a secondary modulator operatively connected to said primary modulator for receiving the modulated first data items, and modulating the primary modulated first data items for transmission to said receiver communication system through said transmitter/receiver,
said data receiver comprising:
a demodulator operatively connected to said transmitter/receiver for receiving an input signal including data blocks which are interleaved from a transmitter communication system, which has the same configuration as said multicarrier wireless communication system, through said transmitter/receiver, demodulating the input signal in a form of second data items corresponding to the respective carriers, and assigning the second data items to the respective carriers;
a decoder operatively connected to said divider for receiving the second data items, and decoding the second data items by use of the modulation schemes which are used for modulating the respective carriers;
a buffer operatively connected to said decoder for receiving and storing the second data items decoded by said decoder;
a data reconstructor operatively connected to said decoder for receiving the decoded second data items and reconstructing the interleaved data blocks from the decoded second data items;
a de-interleave unit operatively connected to said data reconstructor for receiving and de-interleaving the interleaved data blocks into the data blocks separated;
an error corrector operatively connected to said de-interleave unit for receiving the data blocks and correcting an error bit contained in the data blocks on a basis of error correction codes added to the data blocks;
an second error correction code adder operatively connected to said error corrector for receiving the error corrected data blocks, and adding an error correction code to each error corrected data block;
a second interleave unit operatively connected to said second error correction code adder for receiving and interleaving the data blocks to which the error correction codes are added;
a second data divider operatively connected to said second interleave unit for receiving the interleaved data blocks, dividing the interleaved data blocks into third data items, and assigning the third data items to the respective carriers;
an error detector operatively connected to said second data divider and said buffer for receiving the third data items from said second data divider and the decoded second data items from said buffer, and comparing the decoded second data items with the third data items to detect a number of the corrected error bits of each data block contained in the third data items and assigned to the carrier; and
an optimal modulation scheme selector operatively connected to said error detector and said transmitter/receiver for receiving information about the number of the corrected error bits, and determining whether or not the modulation scheme used by each carrier is to be switched on the basis of the information on the number of the corrected error bits of the carrier,
said optimal modulation scheme selector transmitting, if it is determined that the modulation scheme used by one of the carriers is to be switched, the appropriate modulation scheme notification indicative of an optimal modulation scheme on the basis of the determination through said transmitter/receiver to said transmitter communication system.

14. The multicarrier communication system in accordance with claim 13, wherein said data reconstructor is connected to said decoder through said buffer and receives the decoded second data items from said buffer.

15. The multicarrier communication system in accordance with claim 13, wherein, when the information on the number of the corrected error bits of one of the carriers indicates that the bit error rate has increased, the modulation scheme used by the one carrier is switched to a modulation scheme having a lower data conveying capability.

16. The multicarrier communication system in accordance with claim 13, wherein, when the information on the number of the corrected error bits of one of the carriers indicates that the bit error rate has decreased, the modulation scheme used by the one carrier is switched to a modulation scheme having a higher data conveying capability.
